(19) United States
(12) Patent Application Publication
(10) Pub. No.: US 2026/0282817 A1
(43) Pub. Date: Sep. 17, 2026

(54) FILM TRAY SEMICONDUCTOR CHIP CARRIER

(71) Applicant: Arm Limited, Cambridge (GB)

(72) Inventors: Cameron Cole Nelson, Gilbert, AZ (US); George John Scott, Chandler, AZ (US); Javier DeLaCruz, San Jose, CA (US)

(21) Appl. No.: 19/081,961

(22) Filed: Mar. 17, 2025

(51) Int. Cl. H01L 21/673; H01L 21/683

(52) U.S. Cl. CPC H10P 72/165; H10P 72/1904; H10P 72/1918; H10P 72/1928; H10P 72/7402; H10P 72/741; H10P 72/7428; H10P 72/744

(57) ABSTRACT

A chiplet carrier assembly comprises a rigid frame comprising a plurality of openings, and a film coated with an adhesive and mounted within the frame spanning at least a portion of the plurality of openings. The plurality of openings is adapted to receive one or more associated integrated circuit dice to be mounted on the film covered with the adhesive. The rigid frame may comprises a standard JEDEC-size frame, and may comprise one or more vent holes formed in the rigid frame or the film, or a combination thereof, for pressure equalization. The rigid frames may be configured to interlock when stacked, and one or more top and/or bottom covers may be similarly provided to interlock with the stacked rigid frames and to protect toe integrated circuit dice, such as when nitrogen purging a bagged stack of chiplet carrier assemblies.

### FIELD

The field relates to handling integrated circuit semiconductor devices, and more specifically to a film tray semiconductor chip carrier.

### BACKGROUND

Modern computerized devices process and store information in a variety of ways, including using processors that may have multiple cores, cache memory, and other features that contribute to an ever-increasing transistor count per processor. The processors in modern high-performance consumer electronics devices such as smart phones, tablet computers, set top boxes, and the like, may have multiple processor cores, graphics engines, artificial intelligence or neural network processors, cache memory, and a variety of other such functions on a single integrated circuit, or distributed among a number of chiplets that are packaged in the same integrated circuit package. The number of transistors on an integrated circuit therefore continues to grow, as does the power dissipated by an integrated circuit for a given process size (or device pitch size).

Chiplets may be provided as bare integrated circuits that are integrated with other integrated circuits into a single package, such a System-on-Chip or SoC. Such chiplets may therefore not be packaged before delivery to a system manufacturer, such as lacking a metal cover, leads, a flip-chip ball grid array substrate, or other package elements commonly found with integrated circuit processors. Chiplets may also give device manufacturers the ability to produce custom assemblies of different integrated circuit devices, providing for a greater degree of flexibility and scalability than traditional integrated circuits. Splitting the functionality of a very large integrated circuit into multiple chiplets may also increase the yield and improve cost efficiency of the semiconductor manufacturing process, as very large integrated circuits may typically have proportionately larger defect and discard rates. Some manufacturers therefore may desire receiving processor cores or other such integrated circuit devices as chiplets or integrated circuit chips, rather than a packaged integrated circuit device.

Semiconductor devices such as processors and other integrated circuits are typically formed on wafers of silicon (or another semiconductor) that may be in the tens of centimeters in diameter, and the wafer may be cut into individual dice for testing and packaging after integrated circuit formation. Once the wafer semiconductor devices have been formed on a silicon wafer, the wafer may be mounted on a plastic adhesive tape held tight by a ring for further handling. The individual semiconductor devices on the wafer may be cut into dice or chiplets during a dicing process, and the individual dice may be tested and defective dice marked or discarded. Moving a wafer from machine to machine, such as between a lithography machine to form a semiconductor circuit on the wafer and a dicing machine may often be automated, using robotic machines to handle wafers mounted to wafer frames, to cut wafers into dice, and the like.

But, providing bare chiplets or integrated circuit dice to a device manufacturer may pose challenges in that the integrated circuit dice or chiplets may not be protected by packaging yet, and handling or shipping such semiconductor devices may subject them to damage if performed manually or if the semiconductor devices are not protected. For reasons such as these, a need exists for improved handling of semiconductor devices such as integrated circuit dice or chiplets, such as when these devices are shipped between manufacturing facilities.

### BRIEF DESCRIPTION OF THE DRAWINGS

The claims provided in this application are not limited by the examples provided in the specification or drawings, but their organization and/or method of operation, together with features, and/or advantages may be best understood by reference to the examples provided in the following detailed description and in the drawings, in which:

FIG. 1 shows a chiplet carrier, consistent with an example embodiment.

FIG. 2 shows an assembly of stacked interlocking chiplet carriers, consistent with an example embodiment.

FIG. 3 shows a chiplet carrier having a two-piece carrier frame, consistent with an example embodiment.

FIG. 4 shows a chiplet carrier using pin extraction of chiplets, consistent with an example embodiment.

FIG. 5 shows a chiplet carrier using ultraviolet adhesive debonding of chiplets, consistent with an example embodiment.

FIG. 6 shows a stack of interlocking chiplet carrier assemblies in a nitrogen-purged bag for transport, consistent with an example embodiment.

FIG. 7 is a flow diagram of a method of employing chiplet carriers to transport chiplets or integrated circuit dice, consistent with an example embodiment.

FIG. 8 shows a block diagram of a general-purpose computerized system, consistent with an example embodiment.

Reference is made in the following detailed description to accompanying drawings, which form a part hereof, wherein like numerals may designate like parts throughout that are corresponding and/or analogous. The figures have not necessarily been drawn to scale, such as for simplicity and/or clarity of illustration. For example, dimensions of some aspects may be exaggerated relative to others. Other embodiments may be utilized, and structural and/or other changes may be made without departing from what is claimed. Directions and/or references, for example, such as up, down, top, bottom, and so on, may be used to facilitate discussion of drawings and are not intended to restrict application of claimed subject matter. The following detailed description therefore does not limit the claimed subject matter and/or equivalents.

### DETAILED DESCRIPTION

In the following detailed description of example embodiments, reference is made to specific example embodiments by way of drawings and illustrations. These examples are described in sufficient detail to enable those skilled in the art to practice what is described, and serve to illustrate how elements of these examples may be applied to various purposes or embodiments. Other embodiments exist, and logical, mechanical, electrical, and other changes may be made.

Features or limitations of various embodiments described herein, however important to the example embodiments in which they are incorporated, do not limit other embodiments, and any reference to the elements, operation, and application of the examples serve only to aid in understanding these example embodiments. Features or elements shown in various examples described herein can be combined in ways other than shown in the examples, and any such combinations is explicitly contemplated to be within the scope of the examples presented here. The following detailed description does not, therefore, limit the scope of what is claimed.

Many modern computing systems employ processors with multiple processing cores, such that certain tasks that can be performed in parallel can be distributed among the cores for faster execution or different tasks can be performed simultaneously by different processors. The integrated circuits upon which processor cores are formed may also contain graphics processors, such as are able to render graphical images at high speed, encode and decode various video formats, and the like. Sone processor integrated circuits also include artificial intelligence processing, such as neural network processors or the like that may be used to provide various functions such as chatbots, self-driving vehicles, and various other such functions. Processor and graphics cores may also use a local cache memory, such as a bank of static random access memory (SRAM), to provide fast access to data that is currently being processed or that is used frequently. These increases in functionality result in significant increases in transistor count in the integrated circuit, which may add to the integrated circuit's physical size, power consumed, and number of external connections.

Semiconductor devices such as these may therefore be provided as integrated circuit dice or chips having different functions, commonly called “chiplets,” such as where processor cores, a graphics processing unit, and cache memory are provided on different integrated circuits. This may have several advantages for the end product manufacturer, including reduced cost due to higher yields for the individual chiplets, the ability to somewhat customize selection of various chiplets for a particular application, and the ability to package the chiplets in a way that may best suit a particular electronic device. But, sending semiconductor devices such as chiplets or integrated circuit dice from a semiconductor fabrication facility to another facility for integration into an electronic device may introduce manual handling of chiplets and a risk of contamination or damage if not handled carefully.

Chiplet manufacturers may not wish to send an entire wafer, such as a diced or cut wafer in a wafer frame, for several reasons. The number of chiplets in the wafer frame may vary from wafer to wafer based on yield, and the manufacturer may not wish to ship units with varying numbers of components per package or reveal the yield for a provided integrated circuit to the end user. Sending an entire wafer in a wafer carrier, such as a diced or cut wafer attached to a film held in a wafer frame, may further not be desirable in that wafer frames for large wafers typically are not strong enough to prevent deflection or warping during handling, and are designed to be carried in Front Opening Unified Pods (or FOUPs) or Front Opening Shipping Boxes (or FOSBs) for environmental protection during handling. The film held by a wafer frame may not be tight after removing bad dice, and attempts to strengthen the wafer frame such as using aluminum wafer frames may add undesired weight or size to the wafer frame assembly.

Other common electrical component carrier methods, such as mounting chiplets to reel and tape, would not protect the active device side of a chiplet or protect the bumps of a ball grid array and would not accommodate large devices well. Large chiplets such as processors, graphic processing units (GPUs), and large cache memories do not currently have a handling and shipping solution significantly robust to ensure safe delivery such as between manufacturing facilities.

Some examples provided herein therefore provide for a chiplet carrier, such as a rigid frame having a plurality of openings formed therein to accommodate a film coated with adhesive that is configured to receive integrated circuit dice or chiplets. The chiplet carrier in various embodiments may be configured to be stackable and may interlock with other carriers when stacked, may be the size of a standard JEDEC (Joint Electron Device Engineering Council) tray, and may include one or more vent holes such as to accommodate nitrogen purging when preparing a bagged stack of carriers for shipping.

In one such example, a chiplet carrier comprises a rigid frame comprising a plurality of openings, and a film coated with an adhesive and mounted within the frame spanning at least a portion of the plurality of openings. The plurality of openings is adapted to receive one or more associated integrated circuit dice to be mounted on the film covered with the adhesive.

In another example, a method of using a chiplet carrier comprises mounting a film coated with an adhesive within a rigid frame comprising a plurality of openings, the film spanning the plurality of openings, and attaching a plurality of integrated circuit dice to the adhesive coating, each of the plurality of dice to be attached within one of the plurality of openings in the rigid frame.

In another example, a chiplet carrier comprises a rigid frame comprising a plurality of openings, and at least one film mounted within the frame, at least two of the plurality of openings spanned by the at least one film. A plurality of integrated circuits are mounted on the at least one film within one of the plurality of openings in the rigid frame. Integrated circuits may in various examples comprise integrated circuit dice, chiplets, modules comprising multiple chiplets or integrated circuit dice, or any other such circuit components or combination of circuit components.

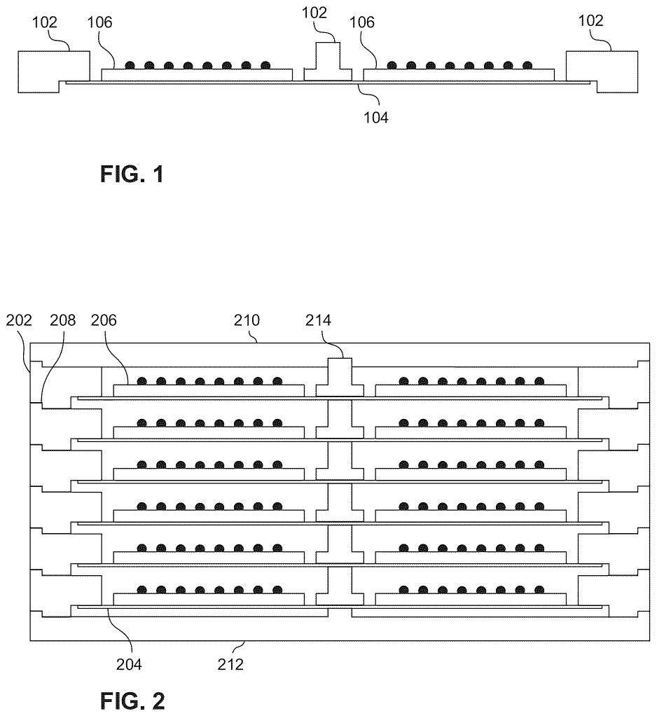

FIG. 1 shows a chiplet carrier, consistent with an example embodiment. Here, a chiplet carrier frame 102, such as a plastic or polymer frame, has an adhesive film 104 attached to the frame configured to accommodate a plurality of chiplets or integrated circuit dice 106 in a corresponding plurality of openings in the frame. The frame in some examples may be the size of a standard JEDEC (Joint Electron Device Engineering Council) tray, such as a 322.6×136 mm tray or other such tray as further defined in JEDEC Publication 95, or other such or future standards, enabling them to be easily handled by common or existing circuit component handling equipment.

The adhesive film 104 may be coated in an adhesive that can be overcome by pressing on the bottom of the film such as with release pins to release the chiplet 106, or may be ultraviolet-sensitive adhesive that substantially loses its adhesive properties when exposed to ultraviolet light. The integrated circuit die 106 may be a chiplet, or may be a complete integrated circuit. Opening sizes in the carrier may be changed in various examples to accommodate different chiplet or integrated circuit sizes, such as small openings for small chiplets or large openings for large integrated circuits such as 30 mm or greater in width or length.

Because the individual chiplets can be cut, tested, and picked from the wafer tray before placement in the chiplet carrier, the chiplet carrier tray of FIG. 1 can be populated to carry only known good chiplets. This may eliminate concerns with providing wafers to device manufacturers such as over varying numbers of defective chiplets per wafer and over revealing the yield of the foundry providing the chiplets to the end user. The tray of FIG. 1 may be reused by removing the adhesive film 104, cleaning the carrier frame 102, and applying a new adhesive film before using the chiplet carrier to carry a new batch of chiplets.

The chiplet carriers may be configured to be stackable, such as to interlock with chiplet carriers of the same design when stacked above or below each other. In one such example, the chiplet carrier's carrier frame 102 may have one or more interlocking features on the top of each carrier frame that mate with corresponding interlocking features on the bottom of each carrier frame. Interlocking features may help secure the chiplet carriers for transport, such as for a number of chiplet carrier frames to be stacked and placed in an electrostatic discharge-safe bag that is purged with nitrogen before being sealed and shipped to secure the integrated circuit dice or chiplets from damage during transport. The carrier frames may in some further examples comprise vent holes, providing for pressure equalization and facilitating gas flow during nitrogen purging. The nitrogen purging process may comprise drawing a vacuum and backfilling with nitrogen in some examples, such that pressure variations within the bag may be observed during the nitrogen purging process. Vent holes in the carrier frames may help reduce pressure variations within the chiplet carrier assemblies during such purging processes, and improve the degree top which existing gases are purged with nitrogen.

The carrier frame 102, the adhesive film 104, or a combination thereof may further comprise electrostatic discharge-safe (ESD-safe) material, such as a conductive metal or an ESD-safe polymer having conductive material embedded therein. The carrier frame may in some examples comprises multiple pieces, such as a top and a bottom piece assembled to secure the adhesive film 104 between the top and bottom pieces of the carrier frame. Capturing or sandwiching the adhesive film between different elements of the chiplet carrier assembly may in some examples shield the portion of the film adhering the film to the carrier frame from ultraviolet light, such that when ultraviolet light is used to deactivate the adhesive coating adhering integrated circuits or chiplets 106 to the film, the film remains adhered to the carrier frame.

In some further embodiments, the chiplet carrier assemblies shown in FIG. 1 may be augmented by top and/or bottom covers configured to mate with the carrier frames, such as when several frames are stacked, bagged, and purged for transport. The covers in some such examples may help prevent the bag from touching the integrated circuit dice or chiplets, or may protect them from inadvertent physical damage better than the bag alone. In some such examples, the covers may provide additional rigidity during a nitrogen purge process, such as drawing a partial vacuum, and support the bag from collapsing in on the top or bottom of the stack of chiplet carrier trays.

FIG. 2 shows an assembly of stacked interlocking chiplet carriers, consistent with an example embodiment. Here, an assembly of chiplet carriers are stacked on each other, with each chiplet carrier having interlocking carrier frame features that interlock with chiplet carriers stacked above or below one another. The chiplet carrier frame 202 in this example has an adhesive film 204 attached to various portions of the frame, and comprises a plurality of openings that are spanned by the adhesive film to accommodate integrated circuit dice or chiplets 206. The integrated circuit dice may be attached to the adhesive film with a wafer side facing the adhesive, such that the active device side of the integrated circuit die with the solder bump array is facing upward and not in contact with anything during transport.

The carrier frames 202 in this example are not uniformly flat on top and bottom as shown in the example of FIG. 1, but comprise one or more alignment feature 208 such as raised portions or recessed portions. In a more detailed example, one or more alignment features such as a raised portion 208 on the top of the carrier frame 202 are configured to align with one or more corresponding or mating alignment features such as a recessed portion 208 on the bottom of the carrier frame. When the carrier frames are stacked as shown in FIG. 2, the one or more alignment features may keep the trays in alignment with one another, constraining them from sliding out of alignment such as during stacking, bagging, nitrogen purging, or transport.

The example embodiment shown in FIG. 2 further shows a top cover 210 and a bottom cover 212, each configured to align with the mating features 208 of the carrier frames 202. In a more detailed example, the top cover 210 has recesses to align with and mate with corresponding raised portions on the edges of the carrier frame 202, and a recess to align and mate with a center element of the carrier frame as shown at 214. The bottom cover 212 may similarly have one or more raised portions to mate with corresponding recesses in the carrier frame, such as are shown in the perimeter of the carrier frame in this example.

Although the center elements of the stacked carrier frame are not shown as having alignment features or interlocking in the example of FIG. 2, other examples may comprise one or more alignment features such as pins, holes, slots, grooves, tabs, recesses, or the like in the center elements or other elements of the alignment frames, further supporting alignment of the carrier frames, top cover, and bottom cover with one another when chiplet carriers are stacked for handling or transport.

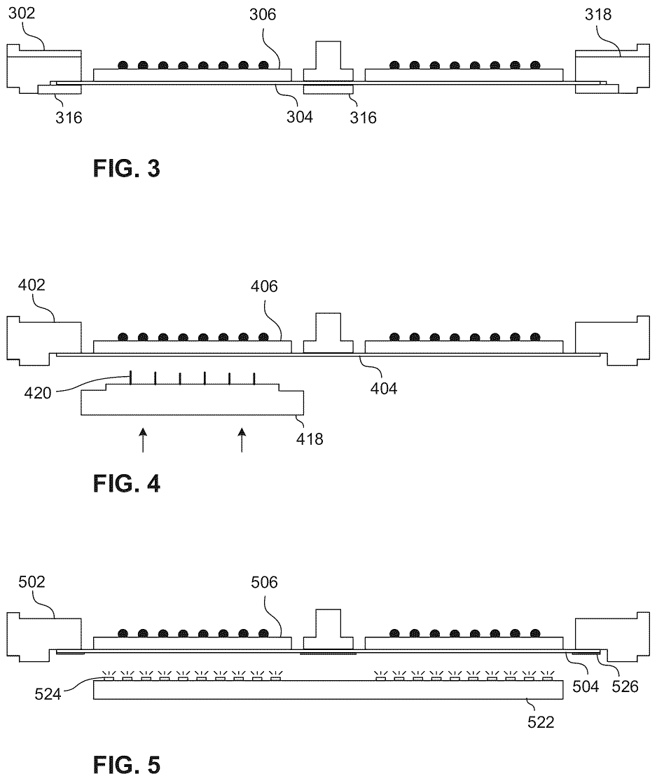

FIG. 3 shows a chiplet carrier having a two-piece carrier frame, consistent with an example embodiment. Here, the carrier frame 302 again comprises a plurality of openings spanned by an attached adhesive film 304, such that chiplets or integrated circuit dice 306 may be attached to the adhesive film such as for processing, storage, or transport. The carrier frame in this example comprises at least a second carrier frame element 316 per carrier frame, configured to capture the adhesive film 304 between the carrier frame 302 and the second carrier frame element 316. The second carrier frame element in this example further serves to shield the adhesive frame from light, such that an ultraviolet-sensitive adhesive that may be deactivated using ultraviolet light will not detach from the carrier frame when exposed to ultraviolet light in the regions in which it is shielded by the second carrier frame element. A more detailed example of shielding a carrier frame portion of an ultraviolet-sensitive adhesive film is shown and described in conjunction with FIG. 5.

The chiplet carrier of FIG. 3 further comprises a vent hole 318, configured to allow air, nitrogen, or other gasses to flow freely from the exterior of the chiplet carrier to the plurality of openings where integrated circuit dice or chiplets 306 reside, including when the chiplet carriers are stacked on each other as in the example of FIG. 2. Because the openings containing the integrated circuit dice may be sealed on all sides by the carrier frame 302 and on the top and bottom by adhesive film 304 and/or top or bottom covers, the vent holes can help facilitate nitrogen purging, including drawing a partial vacuum and backfilling with nitrogen when a stack of chiplet carriers are bagged or boxed for shipment.

FIG. 4 shows a chiplet carrier using pin extraction of chiplets, consistent with an example embodiment. Here, a chiplet carrier assembly comprising a carrier frame 402 and an adhesive film 404 carries a plurality of chiplets or integrated circuit dice 406. The integrated circuit dice 406 are affixed in the assembly by the adhesive of adhesive film 404, which engages with the wafer side of the integrated circuit dice. The opposite side of the integrated circuit dice is the active side on which circuitry is formed, and upon which a flip chip ball grid array of electrical connections has been formed in the example shown here. Mounting the integrated circuit on the wafer side reduces the risk of contamination or physical damage to the active circuitry or electrical connections on the integrated circuit, and provides a flat and uniform surface for adhesion to the adhesive film 404.

When the chiplet carrier is received in a manufacturing facility, the integrated circuit dice or chiplets may be removed from the chiplet carrier in a variety of ways such as using mechanical means to separate the integrated circuit dice from the adhesive film using ultraviolet light to deactivate or reduce the adhesion of the adhesive, or another such method. In the example shown in FIG. 4, a pin ejector 418 comprising a plurality of pins 420 may be used to puncture the adhesive film 404 and push the integrated circuit die 406 clear of the film. The film in some examples may stretch or deform when punctured or pushed by the pin ejector 418, further contributing to separation of the integrated circuit die 406 from the adhesive film 404 due to shear and stretching of the film where it adheres to the integrated circuit die. In alternate embodiments, pins need not puncture the film 404 to release the integrated circuit die, but a pushing element (e.g. in place of pin ejector 418) causing shear and stretching of the film where it adheres to the integrated circuit die may be sufficient to release the die from the film.

In some examples, a tool such as a suction tool, mechanical grabbing tool, or the like may further be employed to capture the freed integrated circuit die 406, and may place it on a circuit board or substrate using traditional pick-and-place methods. In a more detailed example, the tool lifting the freed integrated circuit die from the chiplet carrier assembly may hold the integrated circuit die with the active circuitry and ball grid array contacts facing the tool, and so may transfer the integrated circuit die to another tool that may hold the integrated circuit by the wafer side so that the active side with the electrical contacts can be placed in contact with a circuit board or substrate, such as for solder reflow of the ball grid array.

FIG. 5 shows a chiplet carrier using ultraviolet adhesive debonding of chiplets, consistent with an example embodiment. Here, the carrier frame 502 supports an adhesive film 504 that spans a plurality of openings in the frame, each spanned by the adhesive film. A chiplet or integrated circuit die 506 is mounted to the adhesive film in each opening, and may be released or debonded from the adhesive film by using ultraviolet light to weaken or deactivate the adhesive.

The adhesive film in the example of FIG. 5 may be exposed to ultraviolet light source 522 such as using an ultraviolet lamp, an array of ultraviolet light emitting diodes (LEDs) 524, or the like to at least partially deactivate the adhesive holding the integrated circuit dice 506 to the adhesive film 504. The adhesive film 504 may be shielded from ultraviolet light in part using a mask 526, such as to mask areas of the adhesive film where continued adhesion is desired. In the example of FIG. 5, the adhesive properties of the adhesive film may be desirably maintained in the areas where the adhesive secures the film to the carrier frame 502, as is shown in the region of mask 526, so that the adhesive film remains attached to the carrier frame during debonding the integrated circuit dice and removing them from the chiplet carrier.

Such masking 526 may be avoided in some embodiments, such as the example of FIG. 3, in which the second carrier frame element 316 serves to block ultraviolet light from debonding the adhesive film 304 from the carrier frame 302. To re-use the chiplet carrier of FIG. 3 after the integrated circuit dice or chiplets have been debonded and removed, the second carrier frame element may be detached form the carrier frame assembly, and ultraviolet light, chemicals, or other means may be used to release the adhesive film 304 from the carrier frame 302. A new adhesive film may then be applied, and the second carrier frame element 316 reattached. To re-use the chiplet carrier assembly of FIG. 5 after the integrated circuit dice or chiplets have been debonded and removed, the mask 526 may be removed and the adhesive film may be exposed to ultraviolet light, releasing the adhesive film from the carrier frame 502. New adhesive film 504 and mask 526 may then be applied to prepare the chiplet carrier assembly to carry another batch of chiplets or integrated circuits.

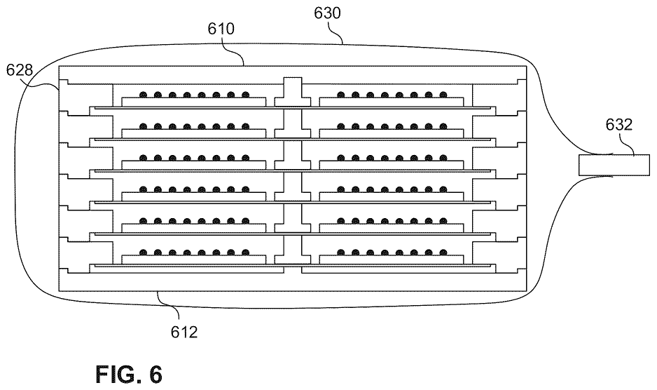

FIG. 6 shows a stack of interlocking chiplet carrier assemblies in a nitrogen-purged bag for transport, consistent with an example embodiment. Here, a plurality of chiplet carrier assemblies 628 are stacked on one another, with an interlocking top cover 610 and bottom cover 612 placed in interlocking positions on the top and bottom of the stack. The stack of chiplet carrier assemblies with the top and bottom covers is placed in an electrostatic discharge (ESD) safe bag 630 in preparation for transport. The top cover 610 and bottom cover 612 may serve to support the bag 630 and prevent it from collapsing in on the chiplet carrier assemblies 628 such as when drawing a vacuum or during transport of the stacked and bagged chiplet carrier assemblies.

The ESD-safe bag 630 may be purged with nitrogen before shipment, such as by forcing nitrogen into the bag while drawing out existing gas. In another example, a partial vacuum may be drawn in the ESD-safe bag 630, and the vacuum backfilled with nitrogen, at least once but preferably multiple times. The bag may be sealed using mechanical means such as a plug 632, or by other means such as by sealing the bag with adhesive or by ultrasonically welding or heat welding the ESD-safe bag closed. In a further example, a plug such as 632 may be configured to facilitate nitrogen purging the bag, such as by having one or more sealable gas ports embedded therein.

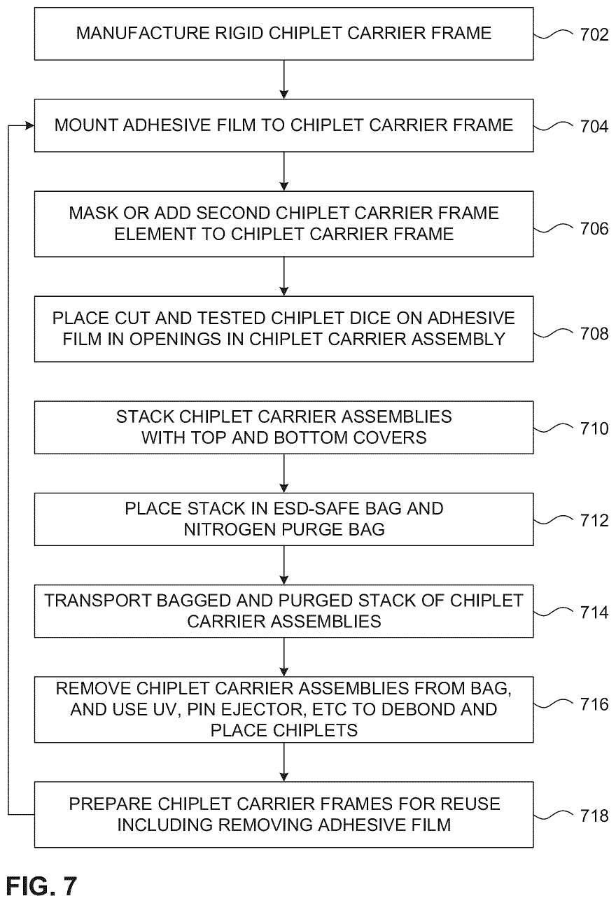

FIG. 7 is a flow diagram of a method of employing chiplet carriers to transport chiplets or integrated circuit dice, consistent with an example embodiment. At 702, a chiplet carrier frame such as that shown at 102 of FIG. 1 is manufactured, such as by injection molding a polymer frame or by other such methods. In some examples, the polymer frame may be ESD-safe, such as having a conductive material embedded therein, to prevent electrostatic buildup or discharge in a chiplet carrier assembly. The chiplet carrier frames are constructed to have a plurality of openings formed therein, which may be spanned by an adhesive film to carry chiplets or integrated circuits. The sizes of such openings may vary depending on the type or size of chiplet to be accommodated. The chiplet carrier frames in some examples may be a standardized size or format, such as the size of a JEDEC (Joint Electron Device Engineering Council) standard tray size to facilitate automated handling of the chiplet carrier frames using existing semiconductor manufacturing equipment.

An adhesive film is mounted to each of the chiplet carrier frames at 702, such that the adhesive film spans the plurality of openings in the carrier frame. The adhesive side of the film is configured to receive the wafer side of a chiplet or integrated circuit die, and the carrier frame provides rigid support for the film and the attached chiplets or dice. A second chiplet carrier frame element, such as is shown in FIG. 3, or a mask as is shown in FIG. 5 may be added to the adhesive film to block ultraviolet light from debonding the adhesive film from the carrier frame during chiplet removal using ultraviolet light deactivation of the adhesive. In other examples, pin ejection or other debonding mechanisms may be used to remove the chiplets or dice from the adhesive film.

The chiplets or integrated circuit dice may be cut from a wafer, tested, and placed on the adhesive film in respective openings in the carrier frame at 708, such as by using a robotic arm with a suction tool, gripper tool, or the like. Only tested good dice or chiplets may be placed in the tray, and bad dice or chiplets may be left on the wafer frame and discarded. This may help ensure that only known good chiplets are sent to the manufacturer, and may help the integrated circuit foundry avoid disclosing trade secret information such as the die yield for a particular product or process.

The chiplet carrier assemblies with integrated circuit dice or chiplets mounted therein may be stacked at 710, and top and/or bottom covers may be added to the stack as shown in the example of FIGS. 2 and 6. The top and bottom covers may help protect the chiplets or dice being carried by the chiplet carrier assemblies, such as by preventing external objects from impacting the chiplets or by supporting an exterior bag during nitrogen purging or drawing a vacuum in the bag. The chiplet carrier stack may be placed in an electrostatic discharge (ESD) safe bag at 712, and the interior of the bag may be purged with nitrogen to ensure a clean environment for the chiplets or dice during transport. In one such example, a partial vacuum may be drawn in the bag and the bag may be backfilled with nitrogen, which may be repeated multiple times to provide a greater degree of nitrogen purging. In another example, gas may be drawn out of the bag while nitrogen is backfilled, reducing or eliminating the need to bring the interior of the bag to lower than atmospheric pressure to purge the bag with nitrogen before the bag is sealed for transport. The ESD-safe bag in some examples may further provide moisture resistance or be configured to provide additional mechanical resistance to puncture, such as having multiple layers. The ESD-safe feature may comprise forming a bag with a surface conductivity within a specified range, such that static electricity is safely drained off or discharged to an ESD-safe workspace or to the atmosphere.

The purged and sealed bag containing the stack of chiplet carrier assemblies may then be transported at 714, until it reaches a destination where the bag may be opened at 716 and the chiplet carrier assemblies removed. The carrier frames may be handled by standard component placement equipment in some embodiments, such as where the carrier frames are a standard JEDEC (Joint Electron Device Engineering Council) tray size such as 322.6×136 mm. The integrated circuit dies may be debonded such as using ultraviolet light as shown in the example of FIG. 5 or using a pin extractor as shown in the example of FIG. 4, and the chiplets or integrated circuit dice may be removed from the deactivated adhesive film and placed on a circuit board or substrate. In a more detailed example, the chiplet may be picked up, such as using a vacuum tool or gripper tool, by its active circuit side having a ball grid array formed thereon, and “handed off” to another tool for placement on a circuit board or substrate with the active circuit side and ball grid array facing the circuit board or substrate.

Once the chiplets or integrated circuit dice have been debonded and removed from the chiplet carrier assembly, the chiplet carrier assembly can be prepared for reuse at 718, such as by removing the adhesive film in preparation for application of new adhesive film at 704. In a more detailed example, the adhesive film may be removed by using ultraviolet light to deactivate the adhesive in at least the regions of the film where the film is adhered to the carrier frame, which may involve removing masking or a second carrier frame element to expose the adhesive film. In other examples, the adhesive film may be removed by mechanical means such as peeling the film from the carrier frame, by chemical means such as using a solvent to deactivate the adhesive, or by other such means.

The examples presented herein describe how a chiplet carrier assembly comprising a frame and an adhesive film may be used to transport chiplets more efficiently than transporting chiplets using wafers or other such methods, and how such chiplet carrier assemblies may be used with common equipment to facilitate automated handling such as tray handling and chiplet pick-and-place during manufacturer use of the transported chiplets or integrated circuit dice. The chiplet carrier assemblies in various examples may comprise interlocking features, top and bottom covers, and other such features to facilitate stacking for shipment, and may comprise vent holes or other such features for nitrogen purging a bagged stack of chiplet carrier assemblies before shipment.

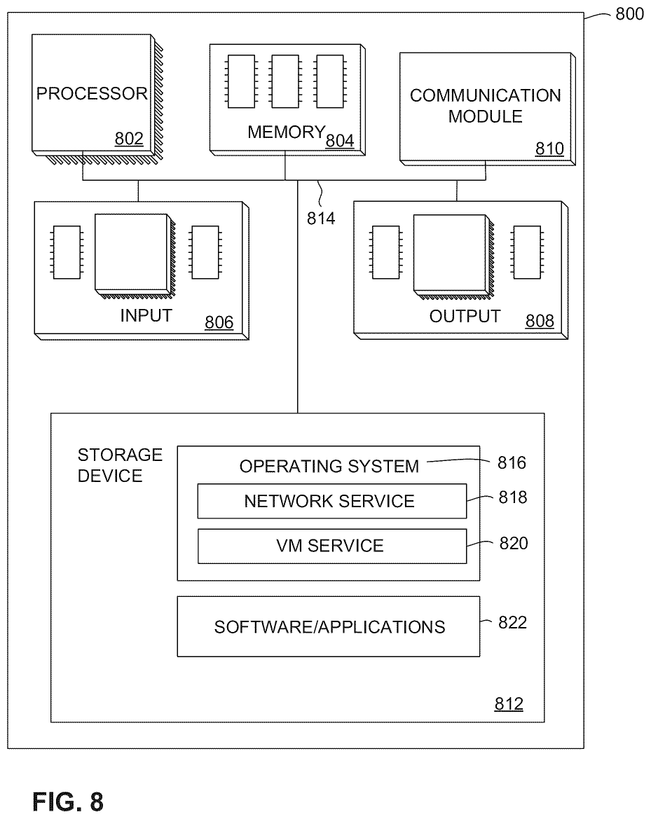

FIG. 8 shows a block diagram of a general-purpose computerized system, consistent with an example embodiment. FIG. 8 illustrates only one particular example of computing device 800, and other computing devices 800 may be used in other embodiments. Although computing device 800 is shown as a standalone computing device, computing device 800 may be any component or system that includes one or more processors or another suitable computing environment for executing software instructions in other examples, and need not include all of the elements shown here.

As shown in the specific example of FIG. 8, computing device 800 includes one or more processors 802, memory 804, one or more input devices 806, one or more output devices 1008, one or more communication modules 810, and one or more storage devices 812. Computing device 800, in one example, further includes an operating system 816 executable by computing device 800. The operating system includes in various examples services such as a network service 818 and a virtual machine service 820 such as a virtual server. One or more applications, such as application 822 are also stored on storage device 812, and are executable by computing device 800.

Each of components 802, 804, 806, 808, 810, and 812 may be interconnected (physically, communicatively, and/or operatively) for inter-component communications, such as via one or more communications channels 814. In some examples, communication channels 814 include a system bus, network connection, inter-processor communication network, or any other channel for communicating data. Applications such as software application 8822 and operating system 816 may also communicate information with one another as well as with other components in computing device 800.

Processors 802, in one example, are configured to implement functionality and/or process instructions for execution within computing device 800. For example, processors 802 may be capable of processing instructions stored in storage device 812 or memory 804. Examples of processors 802 include any one or more of a microprocessor, a controller, a central processing unit (CPU), a graphics processing unit (GPU), a neural processing unit (NPU), an image signal processor (ISP), a digital signal processor (DSP), an application specific integrated circuit (ASIC), a field-programmable gate array (FPGA), or similar discrete or integrated logic circuitry.

One or more storage devices 812 may be configured to store information within computing device 800 during operation. Storage device 812, in some examples, is known as a computer-readable storage medium. In some examples, storage device 812 comprises temporary memory, meaning that a primary purpose of storage device 812 is not long-term storage. Storage device 812 in some examples is a volatile memory, meaning that storage device 812 does not maintain stored contents when computing device 800 is turned off. In other examples, data is loaded from storage device 812 into memory 804 during operation. Examples of volatile memories include random access memories (RAM), dynamic random access memories (DRAM), static random access memories (SRAM), and other forms of volatile memories known in the art. In some examples, storage device 812 is used to store program instructions for execution by processors 802. Storage device 812 and memory 804, in various examples, are used by software or applications running on computing device 800 such as software application 822 to temporarily store information during program execution.

Storage device 812, in some examples, includes one or more computer-readable storage media that may be configured to store larger amounts of information than volatile memory. Storage device 812 may further be configured for long-term storage of information. In some examples, storage devices 812 include non-volatile storage elements. Examples of such non-volatile storage elements include magnetic hard discs, optical discs, floppy discs, flash memories, or forms of electrically programmable memories (EPROM) or electrically erasable and programmable (EEPROM) memories.

Computing device 800, in some examples, also includes one or more communication modules 810. Computing device 800 in one example uses communication module 810 to communicate with external devices via one or more networks, such as one or more wireless networks. Communication module 810 may be a network interface card, such as an Ethernet card, an optical transceiver, a radio frequency transceiver, or any other type of device that can send and/or receive information. Other examples of such network interfaces include Bluetooth, 4G, LTE, or 5G, WiFi radios, and Near-Field Communications (NFC), and Universal Serial Bus (USB). In some examples, computing device 800 uses communication module 810 to wirelessly communicate with an external device such as via a public network.

Computing device 800 also includes in one example one or more input devices 806. Input device 806, in some examples, is configured to receive input from a user through tactile, audio, or video input. Examples of input device 806 include a touchscreen display, a mouse, a keyboard, a voice responsive system, video camera, microphone or any other type of device for detecting input from a user.

One or more output devices 808 may also be included in computing device 800. Output device 808, in some examples, is configured to provide output to a user using tactile, audio, or video stimuli. Output device 808, in one example, includes a display, a sound card, a video graphics adapter card, or any other type of device for converting a signal into an appropriate form understandable to humans or machines. Additional examples of output device 1008 include a speaker, a light-emitting diode (LED) display, a liquid crystal display (LCD or OLED), or any other type of device that can generate output to a user.

Computing device 800 may include operating system 816. Operating system 816, in some examples, controls the operation of components of computing device 800, and provides an interface from various applications such as software application 822 to components of computing device 800. For example, operating system 816, in one example, facilitates the communication of various applications such as software application 822 with processors 802, communication unit 810, storage device 812, input device 806, and output device 808. Applications such as application 822 may include program instructions and/or data that are executable by computing device 800. These and other program instructions or modules may include instructions that cause computing device 800 to perform one or more of the other operations and actions described in the examples presented herein.

Process cores, bitcell arrays, memory structures, peripheral circuitry, and other circuits as described herein in particular examples may be formed in whole or in part by and/or expressed in transistors and/or lower metal interconnects (not shown) in processes (e.g., front end-of-line and/or back-end-of-line processes) such as processes to form complementary metal oxide semiconductor (CMOS) circuitry. The various blocks, neural networks, and other elements disclosed herein may be described using computer aided design tools and expressed (or represented), as data and/or instructions embodied in various computer-readable media, in terms of their behavioral, register transfer, logic component, transistor, layout geometries, and/or other characteristics.

Concepts described herein may be embodied in computer-readable code for fabrication of an apparatus that embodies the described concepts. For example, the computer-readable code can be used at one or more stages of a semiconductor design and fabrication process, including an electronic design automation (EDA) stage, to fabricate an integrated circuit comprising the apparatus embodying the concepts. The above computer-readable code may additionally or alternatively enable the definition, modelling, simulation, verification and/or testing of an apparatus embodying the concepts described herein.

For example, the computer-readable code for fabrication of an apparatus embodying the concepts described herein can be embodied in code defining a hardware description language (HDL) representation of the concepts. For example, the code may define a register-transfer-level (RTL) abstraction of one or more logic circuits for defining an apparatus embodying the concepts. The code may define a HDL representation of the one or more logic circuits embodying the apparatus in Verilog, SystemVerilog, Chisel, or VHDL (Very High-Speed Integrated Circuit Hardware Description Language) as well as intermediate representations such as FIRRTL. Computer-readable code may provide definitions embodying the concept using system-level modelling languages such as SystemC and SystemVerilog or other behavioural representations of the concepts that can be interpreted by a computer to enable simulation, functional and/or formal verification, and testing of the concepts.

Additionally or alternatively, the computer-readable code may define a low-level description of integrated circuit components that embody concepts described herein, such as one or more netlists or integrated circuit layout definitions, including representations such as GDSII. The one or more netlists or other computer-readable representation of integrated circuit components may be generated by applying one or more logic synthesis processes to an RTL representation to generate definitions for use in fabrication of an apparatus embodying the invention. Alternatively or additionally, the one or more logic synthesis processes can generate from the computer-readable code a bitstream to be loaded into a field programmable gate array (FPGA) to configure the FPGA to embody the described concepts. The FPGA may be deployed for the purposes of verification and test of the concepts prior to fabrication in an integrated circuit or the FPGA may be deployed in a product directly.

The computer-readable code may comprise a mix of code representations for fabrication of an apparatus, for example including a mix of one or more of an RTL representation, a netlist representation, or another computer-readable definition to be used in a semiconductor design and fabrication process to fabricate an apparatus embodying the invention. Alternatively or additionally, the concept may be defined in a combination of a computer-readable definition to be used in a semiconductor design and fabrication process to fabricate an apparatus and computer-readable code defining instructions which are to be executed by the defined apparatus once fabricated.

Such computer-readable code can be disposed in any known transitory computer-readable medium (such as wired or wireless transmission of code over a network) or non-transitory computer-readable medium such as semiconductor, magnetic disk, or optical disc. An integrated circuit fabricated using the computer-readable code may comprise components such as one or more of a central processing unit, graphics processing unit, neural processing unit, digital signal processor or other components that individually or collectively embody the concept.

Features of example computing devices employed in example embodiments may comprise features, for example, of a client computing device and/or a server computing device. The term computing device, in general, whether employed as a client and/or as a server, or otherwise, refers at least to a processor and a memory connected by a communication bus. A “processor” and/or “processing circuit” for example, is understood to connote a specific structure such as a central processing unit (CPU), digital signal processor (DSP), graphics processing unit (GPU), image signal processor (ISP) and/or neural processing unit (NPU), or a combination thereof, of a computing device which may include a control unit and an execution unit. In an aspect, a processor and/or processing circuit may comprise a device that fetches, interprets and executes instructions to process input signals to provide output signals. As such, in the context of the present patent application at least, this is understood to refer to sufficient structure within the meaning of 35 USC § 112 (f) so that it is specifically intended that 35 USC § 112 (f) not be implicated by use of the term “computing device,” “processor,” “processing unit,” “processing circuit” and/or similar terms; however, if it is determined, for some reason not immediately apparent, that the foregoing understanding cannot stand and that 35 USC § 112 (f), therefore, necessarily is implicated by the use of the term “computing device” and/or similar terms, then, it is intended, pursuant to that statutory section, that corresponding structure, material and/or acts for performing one or more functions be understood and be interpreted to be described at least in FIG. 1 and in the text associated with the foregoing figure(s) of the present patent application.

Some embodiments may be described, at least in part, by the following numbered clauses or by any combination thereof:
Clause 1: An apparatus, comprising: a rigid frame comprising a plurality of openings; and a film coated with an adhesive and mounted within the frame spanning at least a portion of the plurality of openings; wherein the plurality of openings is adapted to receive one or more associated integrated circuits to be mounted on the film covered with the adhesive.

Clause 2: The apparatus of clause 1, further comprising a plurality of integrated circuit dice, each of the plurality of integrated circuits mounted on the film coated with the adhesive within one of the plurality of openings in the rigid frame.

Clause 3: The apparatus of any of the aforementioned clauses, wherein the rigid frame comprises a standard JEDEC (Joint Electron Device Engineering Council) size frame, such that the rigid frame is configured to be handled by handling equipment designed to handle JEDEC standard trays.

Clause 4: The apparatus of any of the aforementioned clauses, wherein the rigid frame is configured to interlock while stacked on another rigid frame.

Clause 5: The apparatus of any of the aforementioned clauses, further comprising a cover to be disposed over a top of a frame or under a bottom of a frame.

Clause 6: The apparatus of any of the aforementioned clauses, further comprising one or more vent holes formed in the rigid frame or the film, or a combination thereof, for pressure equalization.

Clause 7: The apparatus of any of the aforementioned clauses, wherein at least one of the rigid frame or the film comprises an electrostatic discharge (ESD)-safe polymer.

Clause 8: The apparatus of any of the aforementioned clauses, wherein the film is removably adhered to a bottom side of the rigid frame with the adhesive.

Clause 9: The apparatus of any of the aforementioned clauses, wherein the rigid frame comprises a first rigid frame element and a second rigid frame element, and the film is disposed between the first rigid frame element and the second rigid frame element.

Clause 10: The apparatus of clause 9, wherein the adhesive comprises an ultraviolet debonding adhesive, and the first rigid frame element and the second rigid frame element mask the ultraviolet debonding adhesive while the first rigid frame element and the second rigid frame element are assembled.

Clause 11: A method, comprising: mounting a film coated with an adhesive within a rigid frame comprising a plurality of openings, the film spanning the plurality of openings; and attaching a plurality of integrated circuits to the adhesive coating, each of the plurality of integrated circuits to be attached within one of the plurality of openings in the rigid frame.

Clause 12: The method of clause 11, further comprising adhering the film to a bottom side of the tray using the adhesive.

Clause 13: The method of any of clauses 11-12, wherein the frame comprises a first rigid frame element and a second rigid frame element, and further comprising disposing the film between the first rigid frame element and the second rigid frame element.

Clause 14: The method of any of clauses 11-13, further comprising: stacking a plurality of rigid frames with a plurality of integrated circuit dice attached to each rigid frame, the plurality of rigid frames configured to interlock with one another while stacked; placing the stacked plurality of rigid frames in a bag; gas purging the bag; and sealing the bag.

Clause 15: The method of clause 14, further comprising placing a cover over a top of the stacked plurality of rigid frames or a bottom of the stacked plurality of rigid frames before placement of the stacked plurality of rigid frames in the bag, the cover configured to interlock with one of the plurality of rigid frames.

Clause 16: The method of any of clauses 11-15, further comprising ejecting the plurality of integrated circuit dice from the film coated with adhesive using ultraviolet debonding.

Clause 17: The method of any of clauses 11-16, further comprising ejecting the plurality of integrated circuit dice from the film using one or more ejection pins.

Clause 18: The method of any of clauses 11-17, further comprising handling the rigid frame using handling equipment configured to handle standard JEDEC (Joint Electron Device Engineering Council) trays.

Clause 19: An apparatus, comprising: a rigid frame comprising a plurality of openings; at least one film mounted within the frame, at least two of the plurality of openings spanned by the at least one film; and a plurality of integrated circuits, each of the plurality of integrated circuits mounted on the at least one film within one of the plurality of openings in the rigid frame.

Clause 20: The apparatus of clause 19, wherein the plurality of integrated circuits are mounted on the at least one film with an adhesive.

Although specific embodiments have been illustrated and described herein, any arrangement that achieve the same purpose, structure, or function may be substituted for the specific embodiments shown. This application is intended to cover any adaptations or variations of the example embodiments of the invention described herein. These and other embodiments are within the scope of the following claims and their equivalents.

What is claimed is:

1. An apparatus, comprising:
a rigid frame comprising a plurality of openings; and
a film coated with an adhesive and mounted within the rigid frame spanning at least a portion of the plurality of openings;
wherein the plurality of openings is adapted to receive one or more associated integrated circuits to be mounted on the film covered with the adhesive.

2. The apparatus of claim 1, further comprising a plurality of integrated circuits, each of the plurality of integrated circuits mounted on the film coated with the adhesive within one of the plurality of openings in the rigid frame.

3. The apparatus of claim 1, wherein the rigid frame comprises a standard JEDEC (Joint Electron Device Engineering Council) size frame, such that the rigid frame is configured to be handled by handling equipment designed to handle JEDEC standard trays.

4. The apparatus of claim 1, wherein the rigid frame is configured to interlock while stacked on another rigid frame.

5. The apparatus of claim 1, further comprising a cover to be disposed over a top of a frame or under a bottom of a frame.

6. The apparatus of claim 1, further comprising one or more vent holes formed in the rigid frame or the film, or a combination thereof, for pressure equalization.

7. The apparatus of claim 1, wherein at least one of the rigid frame or the film comprises an electrostatic discharge (ESD)-safe polymer.

8. The apparatus of claim 1, wherein the film is removably adhered to a bottom side of the rigid frame with the adhesive.

9. The apparatus of claim 1, wherein the rigid frame comprises a first rigid frame element and a second rigid frame element, and the film is disposed between the first rigid frame element and the second rigid frame element.

10. The apparatus of claim 9, wherein the adhesive comprises an ultraviolet debonding adhesive, and the first rigid frame element and the second rigid frame element mask the ultraviolet debonding adhesive while the first rigid frame element and the second rigid frame element are assembled.

11. A method, comprising:
mounting a film coated with an adhesive within a rigid frame comprising a plurality of openings, the film spanning the plurality of openings; and
attaching a plurality of integrated circuits to the adhesive coating, each of the plurality of integrated circuits to be attached within one of the plurality of openings in the rigid frame.

12. The method of claim 11, further comprising adhering the film to a bottom side of a tray using the adhesive.

13. The method of claim 11, wherein the rigid frame comprises a first rigid frame element and a second rigid frame element, and further comprising disposing the film between the first rigid frame element and the second rigid frame element.

14. The method of claim 11, further comprising:
stacking a plurality of rigid frames with a plurality of integrated circuits attached to each rigid frame, the plurality of rigid frames configured to interlock with one another while stacked;
placing the stacked plurality of rigid frames in a bag;
gas purging the bag; and
sealing the bag.

15. The method of claim 14, further comprising placing a cover over a top of the stacked plurality of rigid frames or a bottom of the stacked plurality of rigid frames before placement of the stacked plurality of rigid frames in the bag, the cover configured to interlock with one of the plurality of rigid frames.

16. The method of claim 11, further comprising ejecting the plurality of integrated circuits from the film coated with adhesive using ultraviolet debonding.

17. The method of claim 11, further comprising ejecting the plurality of integrated circuits from the film using one or more ejection pins.

18. The method of claim 11, further comprising handling the rigid frame using handling equipment configured to handle standard JEDEC (Joint Electron Device Engineering Council) trays.

19. An apparatus, comprising:
a rigid frame comprising a plurality of openings;
at least one film mounted within the rigid frame, at least two of the plurality of openings spanned by the at least one film; and
a plurality of integrated circuits, each of the plurality of integrated circuits mounted on the at least one film within one of the plurality of openings in the rigid frame.

20. The apparatus of claim 19, wherein the plurality of integrated circuits are mounted on the at least one film with an adhesive.
